(19) United States
(12) Patent Application Publication
(10) Pub. No.: US 2010/0019819 A1
(43) Pub. Date: Jan. 28, 2010

(54) Delay Circuit

(76) Inventors: Chun-Peng Wu, Hsinchu County (TW); Chun Shiah, Hsinchu City (TW); Feng-Chia Chang, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/252,347

(22) Filed: Oct. 15, 2008

(30) Foreign Application Priority Data
Jul. 24, 2008 (TW) 097128108

(51) Int. Cl. H03H 11/26

(52) U.S. Cl. 327/280

(57) ABSTRACT

Constant delay circuit includes signal input end, delay signal output end, RC delay circuit, and a comparator. The signal input end receives an input signal. The delay signal output end outputs the delay input signal, which the delay period is predetermined. The RC delay circuit is coupled to the signal input end for receiving the input signal and generating a voltage. The comparator includes a first input end, a second input end, and an output end. The first end of the comparator is coupled to the RC delay circuit for receiving the voltage. The second end of the comparator receives a reference voltage. The output end of the comparator is coupled to the delay signal output end of the long delay circuit. The comparator compares the reference voltage and the voltage, and accordingly generates a result as the delay signal.

### BACKGROUND OF THE INVENTION

1. Field of the Invention

The present invention relates to a constant long delay circuit, and more particularly, to a long delay circuit using a reference voltage to control the length of the delay without being varied with the process variation.

2. Description of the Prior Art

Please refer to FIG. 1. FIG. 1 is a diagram illustrating a conventional long delay circuit 1 00. The long delay circuit 1 00 comprises delay signal input end, delay signal output end, two inverters INV₁ and INV₂, a resistor R₁, and a capacitor C₁.

The delay signal input end of the long delay circuit 100 receives an input signal V_{IN}, and the delay signal output end of the long delay circuit 100 outputs the delayed signal V_{IN} as the output signal V_{OUT}.

The input end of the inverter INV₁ is coupled to the delay signal input end of the long delay circuit 100 for receiving the input signal V_{IN}, inverting the received signal V_{IN}, and outputting the inverted input signal V_{IN}.

The resistor R₁ is coupled between the output end of the inverter INV₁ and the input end of the inverter INV₂ for receiving the inverted input signal V_{IN}. The voltage on the input end of the inverter INV₂ is voltage V_{X}.

The capacitor C₁ is coupled between the resistor R₁ and the input end of the inverter INV₂ for slowing down the speed of the variation of the voltage V_{X}.

The input end of the inverter INV₂ is coupled to the capacitor C₁, and the output end of the inverter INV₂ is coupled to the delay signal output end of the long delay circuit 100. The inverter INV₂ outputs the output signal V_{OUT} according to the voltage V_{X}. Because of the process variation, the voltage threshold for the input end of the inverter from one process is not exactly the same as that of the inverter from another process. For example, if the voltage threshold for the input end of the inverter INV₂ is the voltage V₁, when the voltage V_{X} on the input end of the inverter INV₂ is lower than the voltage V₁, the output signal V_{OUT} outputted from the inverter INV₂ rises to the high voltage; on the other hand, when the voltage V_{X} on the input end of the inverter INV₂ is not lower than the voltage V₁, the output signal V_{OUT} outputted from the inverter INV₂ keeps at the low voltage instead of rising up to the high voltage. If the voltage threshold for the input end of the inverter INV₂ is the voltage V₂, when the voltage V_{X} on the input end of the inverter INV₂ is lower than the voltage V₂, the output signal V_{OUT} outputted from the inverter INV₂ rises to the high voltage; on the other hand, when the voltage V_{X} on the input end of the inverter INV₂ is not lower than the voltage V₂, the output signal V_{OUT} outputted from the inverter INV₂ keeps at the low voltage instead of rising up to the high voltage.

Please refer to FIG. 2. FIG. 2 is a timing diagram illustrating the conventional long delay circuit 100. As shown in FIG. 2, when the input signal V_{IN} rises from the low voltage to the high voltage, the voltage V_{X} gradually falls from the high voltage to the low voltage because of discharging by the resistor R₁ and the capacitor C₁.

From FIG. 2, it is known that the voltage V_{X} gradually falls. Assuming the voltage VI is higher than the voltage V₂, the voltage V_{X} first falls to the voltage VI, and then falls to the voltage V₂. Thus, if the voltage threshold of the inverter INV₂ is the voltage V1, the inverter INV₂ outputs the output signal V_{OUT} when the voltage V_{X} falls to the voltage V₁, and it is shown in FIG. 2 that the output signal V_{OUT} is delayed than the input signal V_{IN} by the delay time T_{D1}. If the voltage threshold of the inverter INV₂ is the voltage V₂, the inverter INV₂ outputs the output signal V_{OUT} when the voltage V_{X} falls to the voltage V₂, and it is shown in FIG. 2 that the output signal V_{OUT} is delayed than the input signal V_{IN} by the delay time T_{D2}, which is different from the delay time T_{D1}. Therefore, the delay time of the long delay circuit 100 cannot be constant because of the process variation, causing inconvenience.

### SUMMARY OF THE INVENTION

The present invention provides a delay circuit. The delay circuit comprises a signal input end for receiving an input signal; a delay signal output end for outputting an output signal generated from the input signal delayed for a predetermined period; a resistor-capacitor delay circuit, coupled to the signal input end, for receiving the input signal and outputting a voltage signal; and a comparator, comprising a first input end, coupled to the resistor-capacitor delay circuit, for receiving the voltage signal; a second input end for receiving a reference voltage; and an output end, coupled to the delay signal output end, for outputting comparison result of the comparator comparing signals received on the first and the second input ends of the comparator.

The present invention further provides a delay circuit. The delay circuit comprises a passive-component conversion circuit for receiving an initial signal and accordingly outputting a conversion signal; and a comparator, comprising a first input end, coupled to the passive-component conversion circuit, for receiving the conversion signal; a second input end for receiving a reference voltage; and an output end, coupled to the delay signal output end, for outputting comparison result of the comparator comparing signals received on the first and the second input ends of the comparator as a comparison signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a conventional long delay circuit.

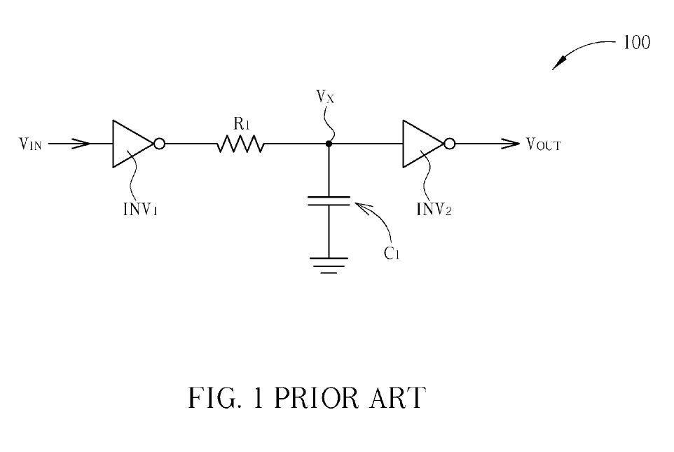

FIG. 2 is a timing diagram illustrating the conventional long delay circuit.

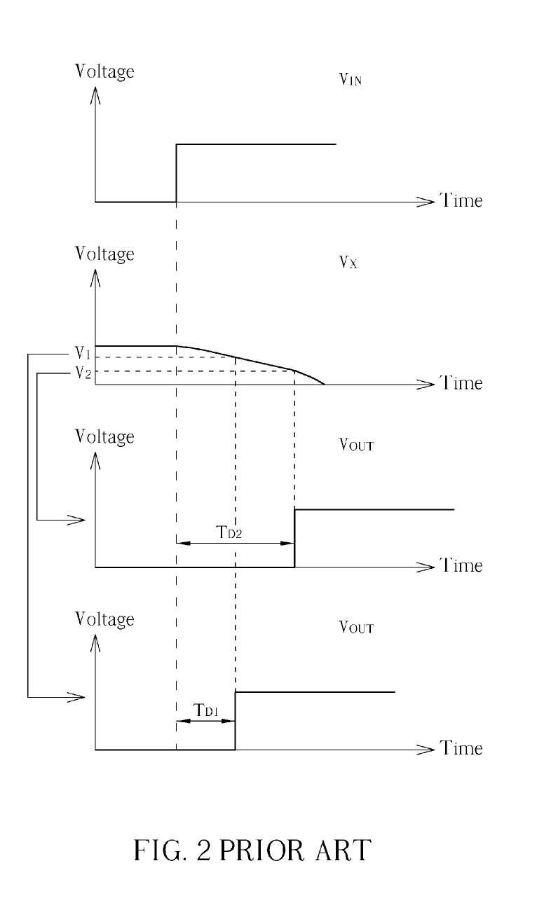

FIG. 3 is a diagram illustrating a long delay circuit according to a first embodiment of the present invention.

FIG. 4 is a timing diagram illustrating the long delay circuit according to the first embodiment of the present invention.

FIG. 5 is a diagram illustrating a long delay circuit according to a second embodiment of the present invention.

FIG. 6 is a diagram illustrating a long delay circuit according to a third embodiment of the present invention.

### DETAILED DESCRIPTION

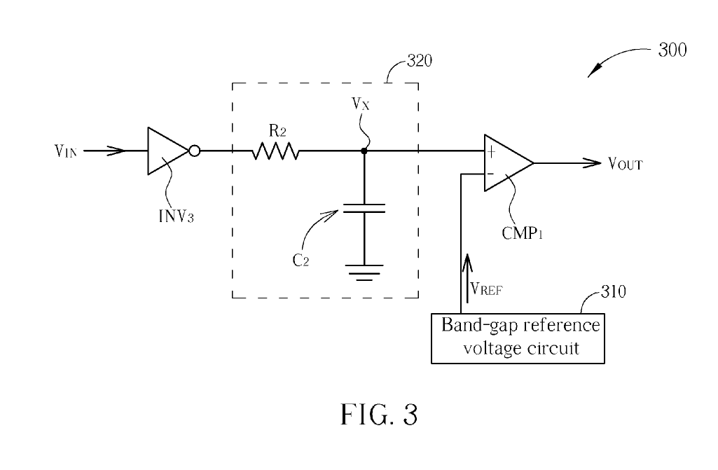

Please refer to FIG. 3. FIG. 3 is a diagram illustrating a long delay circuit 300 according to a first embodiment of the present invention. The long delay circuit 300 comprises a delay signal input end, a delay signal output end, an inverter INV₃, a comparator CMP₁, a band-gap voltage reference circuit 310, and a passive-component conversion circuit 320. The passive-component conversion circuit 320 can be the combination of resistors and capacitors. That is, the passive-component conversion circuit can be realized with a resistor-capacitor delay circuit (RC delay circuit).

The delay signal input end of the long delay circuit 300 receives the input signal V_{IN}, and the delay signal output end of the long delay circuit 300 outputs the delayed input signal V_{IN} as the output signal V_{OUT}.

The input end of the inverter INV₃ is coupled to the delay signal input end of the long delay circuit 300 for receiving the input signal V_{IN} and accordingly outputs the inverted input signal V_{IN} (initial signal).

The passive-component conversion circuit 320 comprises a resistor R₂ and a capacitor C₂. The resistor R₂ is coupled between the output end of the inverter INV₁ and the first input end of the comparator CMP₁ for receiving the inverted input signal V_{IN}. The voltage on the first input end of the comparator CMP₁ is the voltage V_{X}. In the embodiment of FIG. 3, the inverted input signal V_{IN} is utilized as an initial signal for the passive-component conversion circuit 320.

The capacitor C₂ is coupled between the resistor R₂ and the first input end of the comparator CMP₁ for slowing down the speed of variation of the voltage V_{X}. That is, the passive-component conversion circuit 320 converts the initial signal to be the voltage V_{X} and transmits the voltage V_{X} to the comparator CMP₁.

The band-gap reference voltage circuit 310 provides an accurate reference voltage V_{REF}. In one embodiment, the reference voltage V_{REF} is not affected by the process variation, the temperature variation, or the like, and is fixed at the predetermined voltage.

The comparator CMP₁ comprises a first input end (positive end), a second input end (negative end), and an output end. The first input end of the comparator CMP₁ is coupled to the capacitor C₂ for receiving the voltage V_{X}, the second input end of the comparator CMP₂ is coupled to the band-gap reference voltage circuit 310 for receiving the reference voltage V_{REF}, and the output end of the comparator CMP₁ is coupled to the delay signal output end of the long delay circuit 300 for outputting the comparison result (in FIG. 3, the comparison result of the comparator CMP₁ is utilized as the output signal V_{OUT}). When the voltage V_{X} is higher than the reference voltage V_{REF}, the output end of the comparator CMP₁ outputs the low voltage; on the other hand, when the voltage V_{X} is lower than the reference voltage V_{REF}, the output end of the comparator CMP₁ outputs the high voltage.

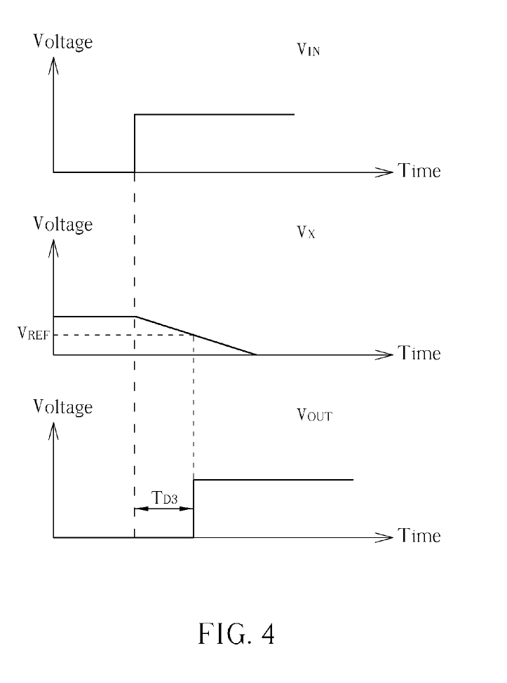

Please refer to FIG. 4. FIG. 4 is a timing diagram illustrating the long delay circuit 300 according to the first embodiment of the present invention. As shown in FIG. 4, when the input signal V_{IN} rises from the low voltage to the high voltage, the voltage V_{X} gradually falls from the high voltage to the low voltage because of discharging by the resistor R₂ and the capacitor C₂.

According to FIG. 4, it is known that the voltage V_{X} falls gradually. Thus, when the voltage V_{X} is still higher than the reference voltage V_{REF}, the output signal V_{OUT} outputted from the comparator CMP₁ still keeps at the low voltage. When the voltage V_{X} falls below the reference voltage V_{REF}, the output signal V_{OUT} outputted from the comparator CMP₁ rises to the high voltage. As shown in FIG. 4, as long as the impedances of the resistors R₂ and the capacitors C₂ keeps the same, the falling speed of the voltage V_{X} keeps the same as well. That is, the period T_{D3} that the voltage V_{X} falls to the reference voltage V_{REF} for is fixed. Thus, the delay time of the output signal V_{OUT} outputted from the comparator CMP₁ can be fixed at the period T_{D3}.

Therefore, the long delay circuit 300 according to the first embodiment of the present invention, outputs a delay signal with a constant delay time without variation due to environmental factors. In other words, the predetermined delay between the input signal V_{IN} and the output signal V_{OUT} (the comparison result) can be fixed and is not affected by the process variation.

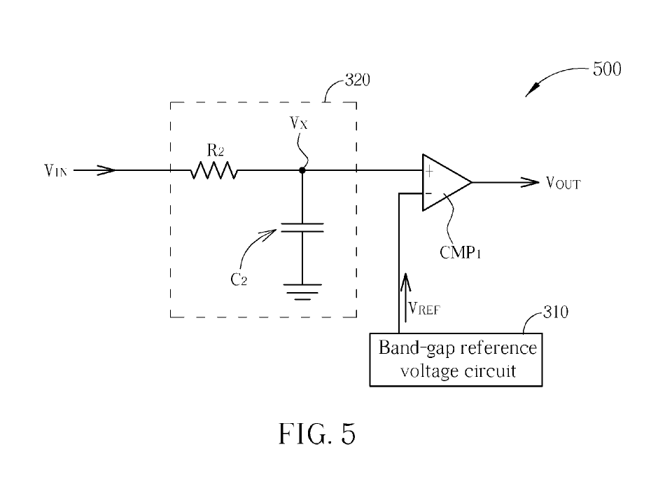

Please refer to FIG. 5. FIG. 5 is a diagram illustrating a long delay circuit 500 according to a second embodiment of the present invention. The long delay circuit 500 comprises a delay signal input end, a delay signal output end, a comparator CMP₁, a band-gap voltage reference circuit 310, and a passive-component conversion circuit 320. The passive-component conversion circuit 320 can be the combination of resistors and capacitors. That is, the passive-component conversion circuit can be realized with a resistor-capacitor delay circuit (RC delay circuit).

The delay signal input end of the long delay circuit 500 receives the input signal V_{IN}, and the delay signal output end of the long delay circuit 500 outputs the delayed input signal V_{IN} as the output signal V_{OUT}.

The passive-component conversion circuit 320 comprises a resistor R₂ and a capacitor C₂. The resistor R₂ is coupled between the delay signal input end and the first input end of the comparator CMP₁ for receiving the input signal V_{IN}. The voltage on the first input end of the comparator CMP₁ is the voltage V_{X}. In the embodiment of FIG. 5, the input signal V_{IN} is utilized as an initial signal for the passive-component conversion circuit 320.

The capacitor C₂ is coupled between the resistor R₂ and the first input end of the comparator CMP₁ for slowing down the speed of variation of the voltage V_{X}. That is, the passive-component conversion circuit 320 converts the initial signal to be the voltage V_{X} and transmits the voltage V_{X} to the comparator CMP₁.

The band-gap reference voltage circuit 310 provides an accurate reference voltage V_{REF}. In one embodiment, the reference voltage V_{REF} is not affected by the process variation, the temperature variation, or the like, and is fixed at the predetermined voltage.

The comparator CMP₁ comprises a first input end (positive end), a second input end (negative end), and an output end. The first input end of the comparator CMP₁ is coupled to the capacitor C₂ for receiving the voltage V_{X}, the second input end of the comparator CMP₂ is coupled to the band-gap reference voltage circuit 310 for receiving the reference voltage V_{REF}, and the output end of the comparator CMP₁ is coupled to the delay signal output end of the long delay circuit 500 for outputting the comparison result (in FIG. 5, the comparison result of the comparator CMP₁ is utilized as the output signal V_{OUT}). When the voltage V_{X} is higher than the reference voltage V_{REF}, the output end of the comparator CMP₁ outputs the low voltage; on the other hand, when the voltage V_{X} is lower than the reference voltage V_{REF}, the output end of the comparator CMP₁ outputs the high voltage. Thus, the long delay circuit 500 according to the second embodiment of the present invention outputs an inverted signal with a constant delay time without variation due to environmental factors.

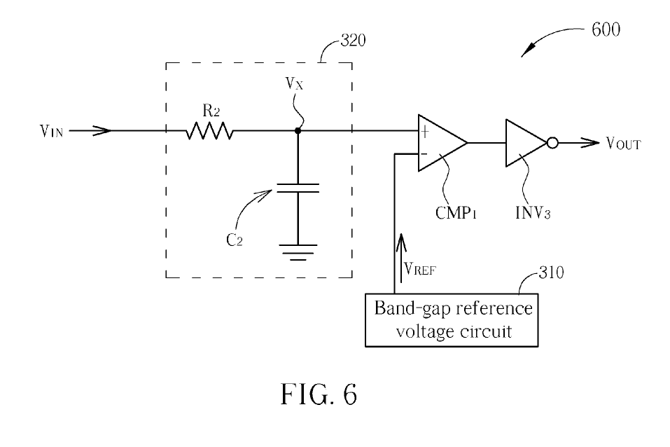

Please refer to FIG. 6. FIG. 6 is a diagram illustrating a long delay circuit 600 according to a third embodiment of the present invention. The long delay circuit 600 comprises a delay signal input end, a delay signal output end, an inverter INV₃, a comparator CMP₁, a band-gap voltage reference circuit 310, and a passive-component conversion circuit 320. The passive-component conversion circuit 320 can be the combination of resistors and capacitors. That is, the passive-component conversion circuit can be realized with a resistor-capacitor delay circuit (RC delay circuit).

The delay signal input end of the long delay circuit 600 receives the input signal V_{IN}, and the delay signal output end of the long delay circuit 600 outputs the delayed input signal V_{IN} after being inverted as the output signal V_{OUT}.

The passive-component conversion circuit 320 comprises a resistor R₂ and a capacitor C₂. The resistor R₂ is coupled between the delay input signal end and the first input end of the comparator CMP₁ for receiving the input signal V_{IN}. The voltage on the first input end of the comparator CMP₁ is the voltage V_{X}. In the embodiment of FIG. 6, the input signal V_{IN} is utilized as an initial signal for the passive-component conversion circuit 320.

The capacitor C₂ is coupled between the resistor R₂ and the first input end of the comparator CMP₁ for slowing down the speed of variation of the voltage V_{X}. That is, the passive-component conversion circuit 320 converts the initial signal to be the voltage V_{X} and transmits the voltage V_{X} to the comparator CMP₁.

The band-gap reference voltage circuit 310 provides an accurate reference voltage V_{REF}. In one embodiment, the reference voltage V_{REF} is not affected by the process variation, the temperature variation, or the like, and is fixed at the predetermined voltage.

The comparator CMP₁ comprises a first input end (positive end), a second input end (negative end), and an output end. The first input end of the comparator CMP₁ is coupled to the capacitor C₂ for receiving the voltage V_{X}, the second input end of the comparator CMP₂ is coupled to the band-gap reference voltage circuit 310 for receiving the reference voltage V_{REF}, and the output end of the comparator CMP₁ is coupled to the input end of the inverter INV₃. When the voltage V_{X} is higher than the reference voltage V_{REF}, the output end of the comparator CMP₁ outputs the low voltage; on the other hand, when the voltage V_{X} is lower than the reference voltage V_{REF}, the output end of the comparator CMP₁ outputs the high voltage. The input end of the inverter INV₃ is coupled to the output end of the comparator CMP₁, the output end of the inverter INV₃ is coupled to the delay signal output end of the long delay circuit 600. The inverter INV₃ outputs output signal V_{OUT} according to the comparison result of the comparator CMP₁. Therefore, the long delay circuit 600 according to the third embodiment of the present invention, outputs a delay signal with a constant delay time without variation due to environmental factors. In other words, the predetermined delay between the input signal V_{IN} (initial signal) and the output signal V_{OUT} can be fixed and is not affected by the process variation.

To sum up, the long delay circuit provided by the present invention provides accurate delay time without being affected by the process variation, the temperature variation, or the like, providing great convenience.

Those skilled in the art will readily observe that numerous modifications and alterations of the device and method may be made while retaining the teachings of the invention.

1. A delay circuit, comprising:
a signal input end for receiving an input signal;
a delay signal output end for outputting an output signal generated from the input signal delayed for a predetermined period;
a resistor-capacitor delay circuit, coupled to the signal input end, for receiving the input signal and outputting a voltage signal;
a comparator, comprising:
a first input end, coupled to the resistor-capacitor delay circuit, for receiving the voltage signal;
a second input end for receiving a reference voltage; and
an output end, coupled to the delay signal output end, for outputting a comparison result of the comparator comparing signals received on the first and the second input ends of the comparator; and
a band-gap reference voltage circuit, coupled to the second input end of the comparator, for generating the reference voltage as a fixed voltage.

2. The delay circuit of claim 1, further comprising an inverter, coupled between the signal input end and the resistor-capacitor delay circuit, for outputting the inverted input signal.

3. The delay circuit of claim 1, further comprising an inverter, coupled to the delay signal output end, for outputting the inverted output signal.

4. The delay circuit of claim 1, wherein the resistor-capacitor delay circuit comprises:
a resistor, coupled between the signal input end and the first input end of the comparator; and
a capacitor coupled between the resistor and a bias source.

5. The delay circuit of claim 4, wherein the bias source is ground.

6. (canceled)

7. A delay circuit, comprising:
a passive-component conversion circuit for receiving an initial signal and accordingly outputting a conversion signal;
a comparator, comprising:
a first input end, coupled to the passive-component conversion circuit, for receiving the conversion signal;
a second input end for receiving a reference voltage; and
an output end, coupled to the delay signal output end, for outputting a comparison result of the comparator comparing signals received on the first and the second input ends of the comparator as a comparison signal; and
a band-gap reference voltage circuit, coupled to the second input end of the comparator, for generating the reference voltage as a fixed voltage.

8. The delay circuit of claim 7, further comprising an inverter,
coupled to the passive-component conversion circuit, for inverting an input signal and accordingly generating the initial signal;
wherein a predetermined period exists between the input signal and the comparison signal.

9. The delay circuit of claim 8, wherein the predetermined period is not affected by process variation.

10. The delay circuit of claim 7, further comprising an inverter,
coupled to the output end of the comparator, for outputting the inverted comparison signal as an output signal;
wherein a predetermined period exists between the initial signal and the output signal.

11. The delay circuit of claim 10, wherein the predetermined period is not affected by process variation.

12. The delay circuit of claim 7, wherein the passive-component conversion circuit comprises:
a resistor, coupled to the first input end of the comparator; and
a capacitor coupled between the resistor and a bias source.

13. The delay circuit of claim 12, wherein the bias source is ground.

14. (canceled)

15. The delay circuit of claim 7, wherein the reference voltage is not affected by process variation.

16. The delay circuit of claim 7, wherein the reference voltage is not affected by temperature variation.
